(19) United States
(12) Patent Application Publication
(10) Pub. No.: US 2017/0194586 A1
(43) Pub. Date: Jul. 6, 2017

(54) ORGANIC LIGHT EMITTING DEVICE

(71) Applicant: LG DISPLAY CO., LTD., SEOUL (KR)

(72) Inventors: Donghyeok LIM, GOYANG-SI (KR); KwanSoo KIM, PAJU-SI (KR)

(73) Assignee: LG DISPLAY CO., LTD., SEOUL (KR)

(21) Appl. No.: 15/225,386

(22) Filed: Aug. 1, 2016

(30) Foreign Application Priority Data
Dec. 31, 2015 (KR) 10-2015-0190915

(51) Int. Cl. H01L 51/50

(52) U.S. Cl. CPC H01L 51/5004; H01L 51/504; H01L 51/5036; H01L 51/5096; H01L 51/5072; H01L 2251/558; H01L 2251/5315; H01L 2251/552

(57) ABSTRACT

Provided is an organic light emitting device with improved luminous efficiency and driving voltage. In the organic light emitting device, formation of a recombination zone inclining to an interface close to an electron transfer layer within an organic emission layer can be minimized. Thus, excitons are more likely to contribute to light emission without being lost. Therefore, luminous efficiency can be improved. Further, in the organic light emitting device, an energy barrier for electrons is minimized in an electron transfer route between the electron transfer layer and the organic emission layer. Therefore, a driving voltage can be improved.

### CROSS-REFERENCE TO RELATED APPLICATIONS

This application claims the priority of Korean Patent Application No. 10-2015-0190915 filed on Dec. 31, 2015, in the Korean Intellectual Property Office, the disclosure of which is incorporated herein by reference.

### BACKGROUND

Field

The present disclosure relates to an organic light emitting device and more particularly, to an organic light emitting device which is further improved in luminous efficiency and driving voltage by optimizing a formation position of a recombination zone.

Description of the Related Art

Recently, as the world enters the information age, the field of display for visually displaying electrical information signals has grown rapidly. Thus, various display devices with excellent characteristics, such as thin and light-weight devices with low power consumption, have been developed.

Specific examples of the display devices include a Liquid Crystal Display (LCD) device, a Plasma Display Panel (PDP) device, a Field Emission Display (FED) device, an Organic Light Emitting Display (OLED) device, and the like.

Particularly, the OLED device uses a self-light emitting element such as an organic light emitting device, and thus has the advantages such as a high response speed and excellent luminous efficiency, driving voltage, contrast ratio, color reproduction rate, brightness and viewing angle as compared with the other display devices.

The organic light emitting device can be used in a lighting device and thus has recently attracted a lot of attention as a new light source from the field of lighting.

The organic light emitting device has a basic structure in which an organic emitting layer is disposed between two electrodes. Electrons and holes are injected into the organic emitting layer from the two electrodes, respectively, and the electrons and holes are combined into excitons in the organic emitting layer. When the generated excitons are subjected to the transition from an excited state to a ground state, lights are emitted from the organic light emitting device.

### SUMMARY

A pixel may include a plurality of sub-pixels. Further, the plurality of sub-pixels may include a red (R) organic light emitting device that emits a red light, a green (G) organic light emitting device that emits a green light, and a blue (B) organic light emitting device that emits a blue light, respectively. As such, the pixel can realize a full color display. Each of the red, green, and blue organic light emitting devices is configured such that a hole is injected into an organic emission layer from a positive electrode and an electron is injected into the organic emission layer from a negative electrode. Herein, a formation position of a recombination zone which is a region where the electron and the hole are combined in the organic emission layer is directly related to internal quantum efficiency (IQE). In this regard, in order to optimize a formation position of the recombination zone, out-coupling relevant to the conditions for light amplification caused by constructive interference may need to be considered as well as luminous efficiency of the organic light emitting device. An optimum position of the organic emission layer in the organic light emitting device structure capable of maximizing out-coupling can be determined, and it is related to external quantum efficiency (EQE). Accordingly, when an organic light emitting device is manufactured, it is important to optimize a formation position of a recombination zone by considering such various sides.

An object to be achieved by the present disclosure is to provide an organic light emitting device which is improved in driving voltage by minimizing an energy barrier to be overcome by an electron in an electron transfer route.

Another object to be achieved by the present disclosure is to provide an organic light emitting device which is improved in luminous efficiency since an organic emission layer includes a recombination zone while satisfying the conditions for light amplification caused by constructive interference.

The objects of the present disclosure are not limited to the aforementioned objects, and other objects, which are not mentioned above, will be apparent to a person having ordinary skill in the art from the following description.

According to an aspect of the present disclosure, there is provided an organic light emitting device. In the organic light emitting device, formation of a recombination zone inclining to an interface close to an electron transfer layer within an organic emission layer can be minimized. Thus, excitons are more likely to contribute to light emission without being lost. Therefore, it is possible to provide an organic light emitting device improved in luminous efficiency. Further, in the organic light emitting device, an energy barrier for electrons is minimized in an electron transfer route between the electron transfer layer and the organic emission layer. Therefore, it is possible to provide an organic light emitting device improved in driving voltage.

According to another aspect of the present disclosure, there is provided an organic light emitting device. The organic light emitting device includes a positive electrode and a negative electrode facing and spaced apart from each other, an organic emission layer including a host material doped with a dopant material, and an electron control layer between the organic emission layer and the cathode and configured to provide an interface with the organic emission layer. The organic light emitting device further includes an electron transfer layer between the electron control layer and the cathode, configured to provide an interface with the electron control layer, having a lower electron mobility than electron mobility of the electron control layer, and having an absolute value of a lowest unoccupied molecular orbital (LUMO) energy level equal to or lower than an absolute value of a LUMO energy level of the electron control layer.

Details of exemplary embodiments of the present disclosure will be included in the detailed description of the disclosure and the accompanying drawings.

According to various exemplary embodiments of the present disclosure, it is possible to provide an organic light emitting device which is improved in driving voltage by minimizing an energy barrier to be overcome by an electron in an electron transfer route.

According to various exemplary embodiments of the present disclosure, it is possible to provide an organic light emitting device which is improved in luminous efficiency since an organic emission layer includes a recombination zone while satisfying the conditions for light amplification caused by constructive interference.

The effects of the present disclosure are not limited to the aforementioned effects, and other effects, which are not mentioned above, will be apparent to a person having ordinary skill in the art from the following description.

The objects to be achieved by the present disclosure, the aspects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A is a cross-sectional view illustrating a structure of an organic light emitting device 1000 according to a first exemplary embodiment of the present disclosure;

FIG. 1B is an LUMO energy diagram illustrating LUMO energy levels of layers respectively corresponding to electron transfer routes in a first emission unit 1100 according to the first exemplary embodiment of the present disclosure;

FIG. 2A is a cross-sectional view illustrating s structure of an organic light emitting device 2000 according to a second exemplary embodiment of the present disclosure;

FIG. 2B is an LUMO energy diagram illustrating LUMO energy levels of layers respectively corresponding to electron transfer routes in a first emission unit 2100 according to the second exemplary embodiment of the present disclosure;

FIG. 3A is a cross-sectional view illustrating a structure of an organic light emitting device 3000 according to a third exemplary embodiment of the present disclosure;

FIG. 3B is an LUMO energy diagram illustrating LUMO energy levels of layers respectively corresponding to electron transfer routes in a first emission unit 3100 according to the third exemplary embodiment of the present disclosure;

FIG. 4A is a cross-sectional view illustrating a structure of an organic light emitting device 4000 according to a fourth exemplary embodiment of the present disclosure; and

FIG. 4B is an LUMO energy diagram illustrating LUMO energy levels of layers respectively corresponding to electron transfer routes in a first emission unit 4100 according to the fourth exemplary embodiment of the present disclosure.

### DETAILED DESCRIPTION OF THE EMBODIMENTS

Advantages and features of the present disclosure, and methods for accomplishing the same will be more clearly understood from various exemplary embodiments described below with reference to the accompanying drawings. However, the present disclosure is not limited to the following various exemplary embodiments but may be implemented in various different forms. The various exemplary embodiments are provided only to complete disclosure of the present disclosure and to fully provide a person having ordinary skill in the art to which the present disclosure pertains with the category of the disclosure, and the present disclosure will be defined by the appended claims.

The shapes, sizes, ratios, angles, numbers, and the like shown in the accompanying drawings for describing the exemplary embodiments of the present disclosure are merely examples, and the present disclosure is not limited thereto. Like reference numerals generally denote like elements throughout the present specification. Further, in the following description, a detailed explanation of well-known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When the time sequence between two or more incidents is described using the terms such as “after”, “subsequent to”, “next to”, and “before”, two or more incidents may be inconsecutive unless the terms are used with the term “immediately” or “directly”.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various exemplary embodiments of the present disclosure can be partially or entirely bonded to or combined with each other and can be interlocked and operated in technically various ways as can be fully understood by a person having ordinary skill in the art, and the various exemplary embodiments can be carried out independently of or in association with each other.

In the present specification, LUMO (Lowest Unoccupied Molecular Orbitals) and HOMO (Highest Occupied Molecular Orbitals) energy levels of a certain layer refer to LUMO and HOMO energy levels of a material, e.g., a host material, accounting for most of the weight ratio of the layer unless the LUMO and HOMO energy levels of a dopant material doped on the layer are specified.

In the present specification, an HOMO energy level may be an energy level measured using CV (Cyclic Voltammetry) by determining an energy level from a relative potential value with respect to a reference electrode of which an electrode potential value is known. For example, an HOMO energy level of a certain material can be measured using ferrocene, of which an oxidation potential value and a reduction potential value are known, as a reference electrode.

In the present specification, the term “doped” means that in a material accounting for most of the weight ratio of a certain layer, another material having different properties (e.g., N-type and P-type, an organic material and an inorganic material) from the material is added at a weight ratio of less than 10%. In other words, a “doped” layer means a layer in which a host material and a dopant material can be identified considering their weight ratios. Further, the term “non-doped” refers to any state other than a state corresponding to the term. “doped”. For example, if a certain layer is formed of a single material or a mixture of materials having identical or similar properties, the layer is a “non-doped” layer. For example, if at least one of materials constituting a certain layer is of P-type and all the materials constituting the layer are not of N-type, the layer is a “non-doped” layer. For example, if at least one of materials constituting a certain layer is an organic material and all the materials constituting the layer are not inorganic materials, the layer is a “non-doped” layer. For example, if all materials constituting a certain layer are organic materials and at least any one of the materials constituting the layer is of N-type and at least another one is of P-type, in case where the N-type material or the P-type material has a weight ratio of less than 10%, the layer is a “doped” layer.

Hereinafter, various exemplary embodiments of the present disclosure will be described in detail with reference to the accompanying drawings.

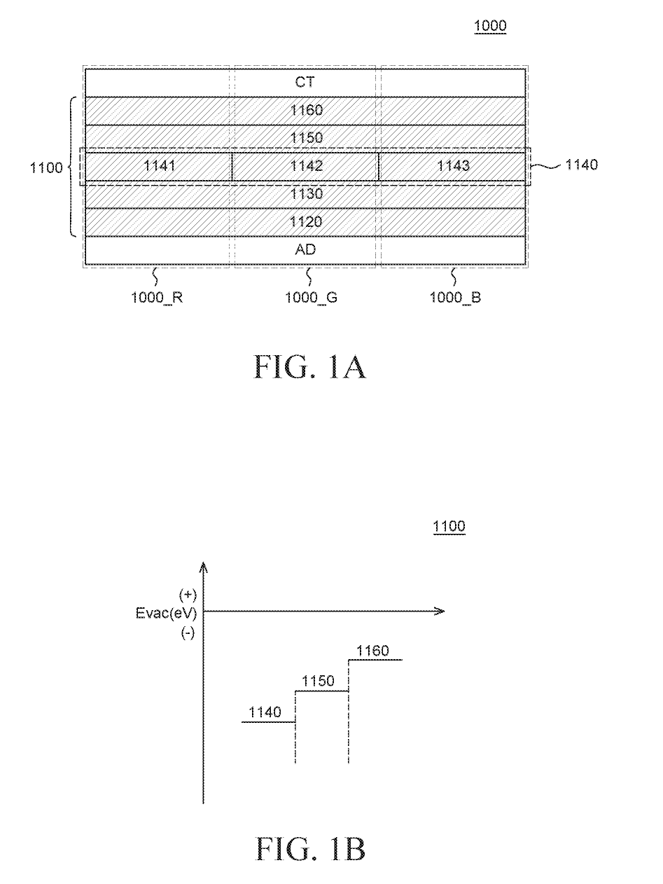

FIG. 1A is a cross-sectional view illustrating a structure of an organic light emitting device 1000 according to a first exemplary embodiment of the present disclosure. All the components of the organic light emitting device according to all embodiments of the present disclosure are operatively coupled and configured.

Referring to FIG. 1, the organic light emitting device 1000 according to the first exemplary embodiment of the present disclosure includes a first emission unit 1100 including a first hole injection layer 1120, a first hole transfer layer 1130, a first organic emission layer 1140, a first electron control layer 1150, and a first electron transfer layer 1160, between a positive electrode AD and a negative electrode CT facing and spaced apart from each other.

An electric field is formed in the organic light emitting device 1000 of the first exemplary embodiment by the positive electrode AD and the negative electrode CT. The positive electrode AD is an anode configured to supply a hole to the organic light emitting device 1000 of the first exemplary embodiment. The anode AD may be formed of a transparent conductive material having a high work function. For example, the anode AD may be formed of a transparent conductive material such as tin oxide (TO), indium tin oxide (ITO), indium zinc oxide (IZO), or indium tin zinc oxide (ITZO), but is not limited thereto. The organic light emitting device 1000 of the first exemplary embodiment may be applied to a top-emission organic light emitting display device configured to emit a light in a direction to the negative electrode CT. In this case, the organic light emitting device 1000 may further include a reflective layer, which is formed of a material such as silver (Ag) or an Ag alloy having an excellent reflectance, in the anode AD. That is, the anode AD may reflect a light generated from the first organic emission layer 1140.

The negative electrode CT is a cathode configured to supply an electron to the organic light emitting device 1000 of the first exemplary embodiment. The cathode CT may be formed of a material having a low work function. For example, the cathode CT may be a transparent conductive material such as transparent conductive oxide (TCO). For example, the cathode CT may be formed of indium tin oxide (ITO), indium zinc oxide (IZO), or indium gallium zinc oxide (IGZO). Otherwise, the cathode CT may be formed of any one or more materials in the group consisting of opaque conductive metals such as magnesium (Mg), silver (Ag), aluminum (Al), calcium (Ca), etc. and alloys thereof. For example, the cathode CT may be formed of an alloy (Mg:Ag) of magnesium (Mg) and silver (Ag). Alternatively, the cathode CT may be formed into two layers of transparent conductive oxide (TCO), indium tin oxide (ITO), indium zinc oxide (IZO), or indium gallium zinc oxide (IGZO) and a metal material such as gold (Au), silver (Ag), aluminum (Al), molybdenum (Mo), or magnesium (Mg), but is not limited thereto. The organic light emitting device 1000 of the first exemplary embodiment may be applied to a top-emission organic light emitting display device. In this case, the cathode CT may be transparent or transflective such that a light generated within the organic light emitting device can be output to the outside through the cathode CT.

If an electric field is formed between the anode AD and the cathode CT, the first hole injection layer 1120 supplies a hole to the first hole transfer layer 1130. The first hole injection layer 1120 is formed of a first hole injection material. For example, the first hole injection material may include HATCN (2,4,5,8,9,11-hexaazatriphenylene-hexanitrile) (dipyrazino[2,3-f:2′,3′-h)quinoxaline-2,3,6,7,10,11-hexacarbonitrile), PEDOT (poly(3,4)-ethylenedioxythiophene), PANI (polyaniline), NPD (N,N′-bis(naphthalene-1-yl)-N,N′-bis(phenyl)-2,2′-dimethylbenzidine), MTDATA (4,4′,4″-tris(3-methylphenylphenylamino)triphenylamine), CuPc (copper phthalocyanine), PEDOT/PSS (poly(3,4-ethylenedioxythiphene, polystyrene sulfonate), etc., but is not limited thereto.

The first hole transfer layer 1130 transfers the supplied hole to the first organic emission layer 1140. The first hole transfer layer 1130 is formed of a first hole transfer material. The first hole transfer material may be a material which is electrochemically stabilized by cationization (i.e., losing an electron). Otherwise, the first hole transfer material may be a material that generates a stable radical cation. Further, the first hole transfer material may be a material that contains aromatic amine and thus can be easily cationized. For example, the first hole transfer material may include any one of NPD (N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), spiro-TAD (2,2′,7,7′-tetrakis(N,N-dimethylamino)-9,9′-spirofluorene), and MTDATA (4,4′,4″-Tris(N-3-methylphenyl-N-phenyl-amino)-triphenylamine), but is not limited thereto.

The first organic emission layer 1140 is disposed between the first hole transfer layer 1130 and the first electron transfer layer 1160. The organic light emitting device 1000 is configured such that excitons are generated by hole-electron combination within the first organic emission layer 1140. The first organic emission layer 1140 includes a material capable of emitting alight of a predetermined color. The first organic emission layer 1140 may have a host-dopant system, i.e., a system in which a first host material having a high weight ratio is doped with a first dopant material contributing to light emission at a weight ratio of 2% to 20% (i.e., in a small amount). The first organic emission layer 1140 may emit a red light, a green light, a blue light, or a yellow-green light, but is not limited thereto. For example, the first organic emission layer 1140 may include a first red organic emission layer, a first green organic emission layer, and a first blue organic emission layer. Thus, a portion where the first red organic emission layer is located between the anode AD and the cathode CT may be referred to as a red sub-organic light emitting device 1000_R. Further, a portion where the first green organic emission layer is located between the anode AD and the cathode CT may be referred to as a green sub-organic light emitting device 1000_G. Furthermore, a portion where the first blue organic emission layer is located between the anode AD and the cathode CT may be referred to as a blue sub-organic light emitting device 1000_B. That is, the organic light emitting device 1000 of the first exemplary embodiment of the present disclosure includes the red sub-organic light emitting device 1000_R, the green sub-organic light emitting device 1000_G, and the blue sub-organic light emitting device 1000_B and thus can realize a full color display.

The organic light emitting device 1000 according to the first exemplary embodiment of the present disclosure may increase external quantum efficiency (EQE) by using an out-coupling effect. To this end, (1) the red sub-organic light emitting device 1000_R may have a thickness for constructive interference of a red light emitted therefrom. Further, (2) the green sub-organic light emitting device 1000_G may have a thickness for constructive interference of a green light emitted therefrom. Furthermore, (1) the blue sub-organic light emitting device 1000_B may have a thickness for constructive interference of a blue light emitted therefrom. Thus, the thickness of the green sub-organic light emitting device 1000_G is smaller than the thickness of the red sub-organic light emitting device 1000_R. Further, the thickness of the blue sub-organic light emitting device 1000_B is smaller than the thickness of the green sub-organic light emitting device 1000_G. Therefore, in the organic light emitting device 1000 according to the first exemplary embodiment of the present disclosure, the blue sub-organic light emitting device 1000_B may have the smallest thickness among the red sub-organic light emitting device 1000_R, the green sub-organic light emitting device 1000_G, and the blue sub-organic light emitting device 1000_B.

If a first red organic emission layer 1141 emits a red light, a host material included in the first red organic emission layer 1141 is a red host material. The red host material may include any one or more of anthracene derivatives such as MADN (2-methyl-9,10-di(2-naphthyl) anthracene), but is not limited thereto. Further, a material used in the first electron transfer layer 1160 to be described later may be used as the red host material. Herein, the red host material may include any one or more of NPD (N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), spiro-TAD (2,2′,7,7′-tetrakis(N,N-dimethylamino)-9,9′-spirofluorene), MTDATA (4,4′,4″-Tris(N-3-methylphenyl-N-phenyl-amino)-triphenylamine), Alq3(Tris(8-hydroxyquinolino)aluminum), Liq(8-hydroxyquinolinolato-lithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, and BAlq(bis(2-methyl-8-quinolinolate)-4-(phenylphenolato)aluminium), SAlq, TPBi(2,2′,2″-(1,3,5-benzinetriyl)-tris(1-phenyl-1-H-benzimidazole), oxadiazole derivatives, triazole derivatives, phenanthroline derivatives, benzoxazole derivatives, or benzthiazole derivatives, but is not limited thereto.

The red host material may be doped with a red dopant material. In this case, the red dopant material may include any one or more of iridium (Ir)-ligand complexes such as Ir(ppy)3 (Tris(2-phenylpyridine)iridium), PIQIr(acac) (bis(1-phenylisoquinoline) acetylacetonate iridium), PQIr(acac) (bis(1-phenylquinoline) acetylacetonate iridium), PQIr(Tris(1-phenylquinoline) iridium) Ir(piq)3(Tris(1-phenylisoquinoline)iridium), and Ir(piq)2(acac)(bis(1-phenylisoquinoline)(acetylacetonate)iridium), pyran derivatives such as PtOEP (Octaethylporphyrinporphine platinum) PBD:Eu(DBM)3(Phen), and DCJTB(4-(dicyanomethylene)-2-tert-butyl-6-(1,1,7,7-tetramethyl julolidyl-9-enyl)-4H), boron derivatives, or perylene derivatives, but is not limited thereto.

If a first green organic emission layer 1142 emits a green light, a host material included in the first green organic emission layer 1142 is a green host material. The green host material may include any one or more of anthracene derivatives such as TBSA (9,10-bis[(2″,7″-di-t-butyl)-9′,9″-spirobifluorenyl]anthracene) and ADN (9,10-di(naphth-2-yl)anthracene), but is not limited thereto. Further, the material used in the first electron transfer layer 1160 to be described later may be used as the green host material. Herein, the green host material may include any one or more of NPD (N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), spiro-TAD (2,2′,7,7′-tetrakis(N,N-dimethylamino)-9,9-spirofluorene), MTDATA (4,4′,4″-Tris(N-3-methylphenyl-N-phenyl-amino)-triphenylamine), Alq3(Tris(8-hydroxyquinolino)aluminum), Liq(8-hydroxyquinolinolato-lithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, and BAlq(bis(2-methyl-8-quinolinolate)-4-(phenylphenolato)aluminium), SAlq, TPBi(2,2′,2″-(1,3,5-benzinetriyl)-tris(1-phenyl-1-H-benzimidazole), oxadiazole derivatives, triazole derivatives, phenanthroline derivatives, benzoxazole derivatives, or benzthiazole derivatives, but is not limited thereto.

The green host material may be doped with a green dopant material. In this case, the green dopant material may include any one or more of iridium (Ir)-ligand complexes including Ir(ppy)3(Tris(2-phenylpyridine)iridium), or Alq3(Tris(8-hydroxyquinolino)aluminum), but is not limited thereto.

If a first blue organic emission layer 1143 emits a blue light, a host material included in the first blue organic emission layer 1143 is a blue host material. The blue host material may include any one or more of anthracene derivatives such as TBSA (9,10-bis[(2″,7″-di-t-butyl)9′,9″-spirobifluorenyl]anthracene), Alq3(Tris(8-hydroxy-quinolino)aluminum), and AND (9,10-di(naphth-2-yl)anthracene), BSBF (2-(9,9′-spirofluoren-2-yl)-9,9′-spirofluorene), CBP (4,4′-bis(carbazol-9-yl)biphenyl), spiro-CBP (2,2′,7,7′-tetrakis(carbazol-9-yl)-9,9′-spirobifluorene), mCP, and TcTa (4,4′,4″-tris(carbazoyl-9-yl)triphenylamine), but is not limited thereto.

The blue host material may be doped with a blue dopant material. The blue dopant material may be a phosphorescent material or a fluorescent material. In this case, the blue dopant material may include any one or more of pyrene substituted with an aryl amine-based compound, iridium (Ir)-ligand complexes including FIrPic(bis(3,5-difluoro-2-(2-pyridyl)phenyl-(2-carboxyprdidyl) iridium) and Ir(ppy)3 (Tris(2-phenylpyridine)iridium), spiro-DPVBi, spiro-6P, spiro-BDAVBi (2,7-bis[4-(diphenylamino)styryl]-9,9′-spirofluorene), distyryl benzene (DSB), distyryl arylene (DSA), polyfluorene (PFO)-based polymers, and poly(p-phenylene vinylene) (PPV)-based polymers, but is not limited thereto.

The first electron control layer 1150 is located between the first organic emission layer 1140 and the cathode CT and is in direct contact with one surface of the first organic emission layer 1140 so as to form an interface. The first electron control layer 1150 is formed of a first electron control material. The first electron control material may be a material which is electrochemically stabilized by anionization (i.e., gaining an electron). Otherwise, the first electron control material may be a material that generates a stable radical anion. Further, the first electron control material may be a material that contains a heterocyclic ring and thus can be easily anionized by a hetero atom. For example, the first electron control material may include any one of Alq3(Tris(8-hydroxyquinolino)aluminum), Liq(8-hydroxyquinolinolato-lithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, and BAlq(bis(2-methyl-8-quinolinolate)-4-(phenylphenolato)aluminium), SAlq, TPBi(2,2′,2″-(1,3,5-benzinetriyl)-tris(1-phenyl-1-H-benzimidazole), oxadiazole, triazole), phenanthroline, benzoxazole, or benzthiazole, but is not limited thereto. For example, the first electron control layer 1150 may include a first electron control material having an LUMO energy level of −2.38 eV and may have an electron mobility of 1.01*10⁻⁴ cm²/V·s. Otherwise, the first electron control layer 1150 may include a first electron control material having an LUMO energy level of −2.45 eV and may have an electron mobility of 3.80*10⁻⁴ cm²/V·s. Further, the first electron control layer 1150 may include a first electron control material having an LUMO energy level of −2.95 eV and may have an electron mobility of 1.51*10⁻⁵ cm²/V·s.

The first electron transfer layer 1160 is supplied with an electron from the cathode CT. Further, the first electron transfer layer 1160 transfers the electron to the first organic emission layer 1140. The first electron transfer layer 1160 is formed of a first electron transfer material. The first electron transfer material may be a material which is electrochemically stabilized by anionization (i.e., gaining an electron). Otherwise, the first electron transfer material may be a material that generates a stable radical anion. Further, the first electron transfer material may be a material that contains a heterocyclic ring and thus can be easily anionized by a hetero atom. The first electron transfer layer 1160 may be formed of a mixture of a plurality of first electron transfer materials. For example, the first electron transfer material may include any one of Alq3(Tris(8-hydroxyquinolino)aluminum), Liq(8-hydroxyquinolinolato-lithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, and BAlq(bis(2-methyl-8-quinolinolate)-4-(phenylphenolato)aluminium), SAlq, TPBi(2,2′,2″-(1,3,5-benzinetriyl)-tris(1-phenyl-1-H-benzimidazole), oxadiazole, triazole, phenanthroline, benzoxazole, or benzthiazole, but is not limited thereto.

The organic light emitting device 1000 according to the first exemplary embodiment of the present disclosure is configured such that an electron movement speed in the first electron control layer 1150 is higher than an electron movement speed in the first electron transfer layer. To this end, the first electron transfer material constituting the first electron transfer layer 1160 is different from the first electron control material constituting the first electron control layer 1150. Otherwise, a combination of a plurality of first electron transfer materials constituting the first electron transfer layer 1160 is a combination of a plurality of first electron control materials constituting the first electron control layer 1150. Further, an electron mobility of the first electron transfer layer 1160 is lower than an electron mobility of the first electron control layer 1150. For example, an electron mobility of the first electron transfer material is lower than an electron mobility of the first electron control material.

In general, in order to maximize luminous efficiency using an out-coupling effect when designing an organic light emitting device, a position of an organic emission layer in the organic light emitting device is important. Thus, the organic light emitting device is designed considering the optical conditions for constructive interference. In this case, a distance from the organic emission layer to an anode is set to be different from a distance from the organic emission layer to a cathode. For example, the distance from the organic emission layer to the anode may be longer than the distance from the organic emission layer to the cathode. Further, a red light, a green light, and a blue light respectively have different wavelengths and thus respectively have different optical conditions for constructive interference. Therefore, the organic light emitting device may include a red sub-organic light emitting device, a green sub-organic light emitting device, and a blue sub-organic light emitting device. In this case, a distance from a red organic emission layer to the anode, a distance from a green organic emission layer to the anode, and a distance from a blue organic emission layer to the anode are different from each other. Specifically, (1) a thickness of the blue sub-organic light emitting device is smaller than a thickness of the red sub-organic light emitting device and a thickness of the green sub-organic light emitting device. Further, (2) the distance from the blue organic emission layer to the anode is shorter than the distance from the red organic emission layer to the anode or the distance from the green organic emission layer to the anode.

A shorter distance from the blue organic emission layer to the anode means that it takes less time for a hole to reach the blue organic emission layer. That is, since the distance from the blue organic emission layer to the anode is short, a hole rapidly reaches the blue organic emission layer. Therefore, a recombination zone may be formed inclining to the cathode rather than the center within the blue organic emission layer or may be formed over an interface on the cathode side of the blue organic emission layer. The recombination zone is slightly inclined within the blue organic emission layer of the organic light emitting device. Thus, some of excitons cannot be converted into light energy, but be converted into heat energy and thus cannot contribute to light emission. Accordingly, luminous efficiency of the organic light emitting device is decreased.

The inventors of the present disclosure recognized that it is necessary to pull a formation region of the recombination zone from the cathode side to the anode side in order to compensate the above-described phenomenon. Therefore, the organic light emitting device 1000 of the first exemplary embodiment of the present disclosure is configured such that an electron can rapidly reach the first organic emission layer 1140 as much as a hole. Specifically, in the organic light emitting device 1000 of the first exemplary embodiment of the present disclosure, the first electron control layer 1150 having a higher electron mobility than the first electron transfer layer 1160 is disposed between the first organic emission layer 1140 and the first electron transfer layer 1160. The first electron control layer 1150 functions as a kind of booster. Thus, an electron more rapidly reaches the first organic emission layer 1140. Therefore, the recombination zone formed by combination of electrons and holes can be located entirely within the first organic emission layer 1140 and light energy can be generated by excitons more effectively.

The above-described effect can be maximized particularly in the blue sub-organic light emitting device 1000_B. The red sub-organic light emitting device 1000_R and the green sub-organic light emitting device 1000_G are thicker than the blue sub-organic light emitting device 1000_B. Thus, if the first electron control layer 1150 is thin enough, a recombination zone of the blue sub-organic light emitting device 1000_B may be optimized with the first electron control layer 1150. Even in this case, the red sub-organic light emitting device 1000_R and the green sub-organic light emitting device 1000_G are not greatly affected. Therefore, in the organic light emitting device 1000 of the first exemplary embodiment, one entire surface of the first organic emission layer 1140 and the first electron control layer 1150 are in direct contact with each other and forms an interface. In other words, all of the first red organic emission layer 1141, the first green organic emission layer 1142, and the first blue organic emission layer 1143 respectively form interfaces with the first electron control layer 1150. Thus, it is not necessary to allow an interface with the first electron control layer 1150 to be present in only some of the red sub-organic light emitting device 1000_R, the green sub-organic light emitting device 1000_G, and the blue sub-organic light emitting device 1000_B. Therefore, it is not necessary to use a fine metal mask in order to form the first electron control layer 1150. As a result, there is no difficulty of aligning sub-organic light emitting devices, and, thus, the organic light emitting device 1000 of the first exemplary embodiment of the present disclosure can be manufactured by a relatively easy process.

The first electron control layer 1150 may be disposed considering optimization of a recombination zone in the blue sub-organic light emitting device 1000_B. In this case, for example, the first electron control layer 1150 may be configured to have a thickness of more than 3% to less than 5% of a thickness of the blue sub-organic light emitting device 1000_B in order not to greatly affect the red sub-organic light emitting device 1000_R or the green sub-organic light emitting device 1000_G. If a thickness of the first electron control layer 1150 is equal to or less than 3% of a thickness of the blue sub-organic light emitting device 1000_B, the above-described effect may not be shown in the blue sub-organic light emitting device 1000_B. Therefore, the first electron control layer 1150 may have a thickness of more than 3% of a thickness of at least the blue sub-organic light emitting device 1000_B. Further, if a thickness of the first electron control layer 1150 is equal to or more than 5% of a thickness of the blue sub-organic light emitting device 1000_B, a position of a recombination zone in each of the red sub-organic light emitting device 1000_R and the green sub-organic light emitting device 1000_G may be changed from an optimum position. Thus, luminous efficiency may be decreased. Specifically, if a thickness of the first electron control layer 1150 is not equal to or more than 5% of a thickness of the blue sub-organic light emitting device 1000_B, even if a distance from the first red organic emission layer 1141 to the cathode CT is slightly increased by the first electron control layer 1150, a position of a recombination zone formed in the first red organic emission layer 1141 is not changed. Otherwise, if a thickness of the first electron control layer 1150 is not equal to or more than 5% of a thickness of the blue sub-organic light emitting device 1000_B, a distance from the first red organic emission layer 1141 to the cathode CT is not increased in spite of addition of the first electron control layer 1150 but an electron more rapidly reaches the first red organic emission layer 114 due to a high electron mobility of the first electron control layer 1150. Even in this case, a position of a recombination zone formed in the first red organic emission layer 1141 is not changed. However, if a thickness of the first electron control layer 1150 is equal to or more than 5% of a thickness of the blue sub-organic light emitting device 1000_B, not only a recombination zone formed in the blue sub-organic light emitting device 1000_B but also a recombination zone formed in the first red organic emission layer 1141 is changed in position. Thus, luminous efficiency of the organic light emitting device 1000 may be decreased. Further, the amount of excitons converted into heat energy is increased, which may accelerate interface degradation and increase a driving voltage. Therefore, the first electron control layer 1150 may have a thickness of less than 5% of a thickness of at least the blue sub-organic light emitting device 1000_B.

Hereinafter, a relationship among the first organic emission layer 1140, the first electron control layer 1150, and the first electron transfer layer 1160 will be described with reference to FIG. 1B.

FIG. 1B is an LUMO energy diagram illustrating LUMO energy levels of layers respectively corresponding to electron transfer routes in the first emission unit 1100 according to the first exemplary embodiment of the present disclosure. The organic light emitting device 1000 according to the first exemplary embodiment of the present disclosure is designed such that an energy barrier is minimized when an electron moves from the first electron transfer layer 1160 to the first organic emission layer 1140. Specifically, if the first organic emission layer 1140 and the first electron control layer 1150 are in contact with each other and form an interface, an absolute value of an LUMO energy level of the first electron control layer 1150 is lower than an absolute value of an LUMO energy level of the first organic emission layer 1140. Further, if the first electron control layer 1150 and the first electron transfer layer 1160 are in contact with each other and form an interface, an absolute value of an LUMO energy level of the first electron transfer layer 1160 is equal to or lower than the absolute value of the LUMO energy level of the first electron control layer 1150. That is, the absolute value of the LUMO energy level of the first electron transfer layer 1160 is equal to or lower than the absolute value of the LUMO energy level of the first electron control layer 1150, and the absolute value of the LUMO energy level of the first electron control layer 1150 is lower than the absolute value of the LUMO energy level of the first organic emission layer 1140. Herein, the absolute value of an LUMO energy level of the first organic emission layer 1140 may be an absolute value of an LUMO energy level of a host material included in the first organic emission layer 1140.

If an electric field is applied to an organic light emitting device, an electron moves along an LUMO energy level of the organic light emitting device. Herein, the electron can easily move from a place having a higher LUMO energy level to a place having a lower LUMO energy level as compared with a case where the electron moves in reverse. That is, the electron can easily move from a place having a lower absolute value of an LUMO energy level to a place having a higher absolute value of an LUMO energy level as compared with a case where the electron moves in reverse. For example, if an electron moves from a place having a higher LUMO energy level to a place having a lower LUMO energy level, it may mean that an energy barrier is not present. It is advantageous to reduce an energy barrier as much as possible in terms of (1) an easiness in movement of an electron and (2) a decrease in interface heating which is a cause of interface degradation.

An absolute value of an LUMO energy level of each of a plurality of host materials (i.e., a red host material, a green host material, and a blue host material) in the first organic emission layer 1140 is higher than the absolute value of the LUMO energy level of the first electron control layer 1150. Thus, an electron can easily move from first electron control layer 1150 to the first organic emission layer 1140. Further, the absolute value of the LUMO energy level of the first electron control layer 1150 is equal to or higher than the absolute value of the LUMO energy level of the first electron transfer layer 1160. Thus, an electron can easily move from the first electron transfer layer 1160 to the first electron control layer 1150.

In other words, among the first organic emission layer 1140, the first electron control layer 1150, and the first electron transfer layer 1160, the first organic emission layer 1140 may have the lowest LUMO energy level and the first electron transfer layer 1160 may have the highest LUMO energy level. This is not necessarily limited to a case where the first organic emission layer 1140, the first electron control layer 1150, and the first electron transfer layer 1160 are in direct contact with each other and form interfaces. Thus, in the organic light emitting device 1000 according to the first exemplary embodiment, an energy barrier to be overcome by an electron moving from the first electron transfer layer 1160 to the first organic emission layer 1140 is minimized. Since the electron can move to the first organic emission layer 1140 without difficulty in overcoming the energy barrier, a driving voltage of the organic light emitting device 1000 can be reduced.

Referring to Table 1 below, the organic light emitting device 1000 according to the first exemplary embodiment of the present disclosure may be configured such that the absolute value of the LUMO energy level of the first electron control layer 1150 is closer to the absolute value of the LUMO energy level of the first electron transfer layer 1160 than to the absolute value of the LUMO energy level of the first organic emission layer 1140.

TABLE 1

| | Variation in driving | Variation in luminous | Electron mobility | LUMO of first | LUMO of first | LUMO of first |
|---|---|---|---|---|---|---|
| | voltage compared with | efficiency compared with | of first electron | organic emission | electron control | electron transfer |
| | Comparative Example | Comparative Example | control layer | layer | layer | layer |
| | (ΔV) | (%) | (cm²/V · s) | (−eV) | (−eV) | (−eV) |
| Comparative | 4.5 V | 100 | — | 3.0 | — | 2.24 |
| Example | | | | | | |
| Example 1_1 | −0.1 ΔV | 110 | 1.01*10⁻⁴ | 3.0 | 2.38 | 2.24 |
| Example 1_2 | −0.1 ΔV | 105 | 3.80*10⁻⁴ | 3.0 | 2.45 | 2.24 |

Comparative Example is a general organic light emitting device in which the first electron control layer 1150 is not inserted. Each of Example 1_1 and Example 1_2 is the organic light emitting device 1000 in which the first electron control layer 1150 is inserted. Example 1_1 and Example 1_2 are identical to each other except a configuration of the first electron control layer 1150. That is, the first electron control layer 1150 of Example 1_1 includes a first electron control material having an LUMO energy level of −2.38 eV and has an electron mobility of 1.01*10⁻⁴ cm²/V·s. The first electron control layer 1150 of Example 1_2 includes a first electron control material having an LUMO energy level of −2.45 eV and has an electron mobility of 3.80*10⁻⁴ cm²/V·s. In other words, in both of Example 1_1 and Example 1_2, an absolute value of an LUMO energy level of the first electron transfer layer 1160 is equal to or lower than an absolute value of an LUMO energy level of the first electron control layer 1150 and the absolute value of the LUMO energy level of the first electron control layer 1150 is lower than an absolute value of an LUMO energy level of the first organic emission layer 1140. It can be seen that both of Example 1_1 and Example 1_2 are improved in driving voltage and luminous efficiency as compared with Comparative Example. Further, it can be seen that although an electron mobility of the first electron control layer 1150 in Example 1_1 is slightly lower than an electron mobility of the first electron control layer 1150 in Example 1_2, luminous efficiency of Example 1_1 is higher than that of Example 1_2. This is because the LUMO energy level of the first electron control layer 1150 is set to be closer to the LUMO energy level of the first electron transfer layer 1160 than to the LUMO energy level of the first electron control layer 1150 of Example 1_2, and, thus, an electron reaching the first organic emission layer 1140 becomes less likely to move back to the first electron control layer 1150. Therefore, in the organic light emitting device 1000 according to the first exemplary embodiment of the present disclosure, the absolute value of the LUMO energy level of the first electron control layer 1150 is closer to the absolute value of the LUMO energy level of the first electron transfer layer 1160 than to the absolute value of the LUMO energy level of the first organic emission layer 1140. Thus, the organic light emitting device 1000 according to the first exemplary embodiment has a more improved electric-light characteristic.

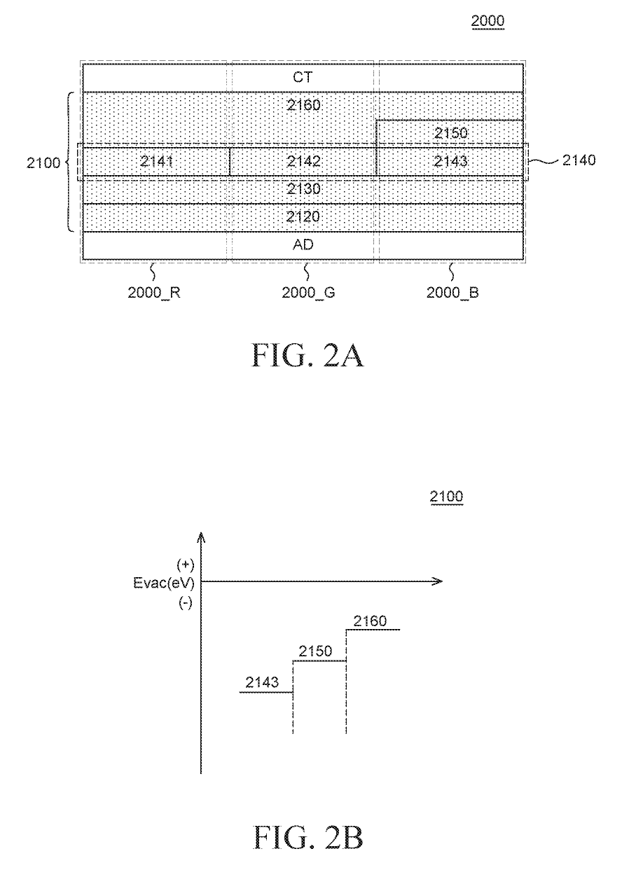

FIG. 2A is a cross-sectional view illustrating an organic light emitting device 2000 according to a second exemplary embodiment of the present disclosure. Referring to FIG. 2A, the organic light emitting device 2000 according to the second exemplary embodiment of the present disclosure includes a first emission unit 2100 including a first hole injection layer 2120, a first hole transfer layer 2130, a first organic emission layer 2140, a first electron control layer 2150, and a first electron transfer layer 2160 between an anode AD and a cathode CT facing and spaced apart from each other.

The same descriptions of the components of the organic light emitting device 1000 according to the first exemplary embodiment of the present disclosure may also be applied to the components of the organic light emitting device 2000 according to the second exemplary embodiment of the present disclosure. That is, the above descriptions of the anode AD, the cathode CT, the first hole injection layer 1120, the first hole transfer layer 1130, the first organic emission layer 1140, the first red organic emission layer 1141, the first green organic emission layer 1142, the first blue organic emission layer 1143, the first electron control layer 1150, and the first electron transfer layer 1160 of the organic light emitting device 1000 according to the first exemplary embodiment of the present disclosure may also be respectively applied to the anode AD, the cathode CT, the first hole injection layer 2120, the first hole transfer layer 2130, the first organic emission layer 2140, a first red organic emission layer 2141, a first green organic emission layer 2142, a first blue organic emission layer 2143, the first electron control layer 2150, and the first electron transfer layer 2160 of the organic light emitting device 2000 according to the second exemplary embodiment of the present disclosure. In describing the organic light emitting device 2000 according to the second exemplary embodiment of the present disclosure, redundant descriptions will be omitted and modified or added parts will be described.

In the organic light emitting device 2000 according to the second exemplary embodiment of the present disclosure, the first electron control layer 2150 having a higher electron mobility than the first electron transfer layer 2160 is disposed between the first blue organic emission layer 2143 and the first electron transfer layer 2160. The first electron control layer 2150 functions as a kind of booster in a blue sub-organic light emitting device 2000_B. Thus, an electron more rapidly reaches the first organic emission layer 2140. Therefore, a recombination zone formed by combination of electrons and holes can be located entirely within the first blue organic emission layer 2143 and light energy can be generated by excitons more effectively.

The above-described effect can be maximized particularly in the blue sub-organic light emitting device 2000_B having a small thickness. The first electron transfer layer 2160 may be disposed only in the blue sub-organic light emitting device 2000_B in order not to affect a red sub-organic light emitting device 2000_R or a green sub-organic light emitting device 2000_G. In other words, in the organic light emitting device 2000 of the second exemplary embodiment, among surfaces of the first organic emission layer 2140, only one surface corresponding to the first blue organic emission layer 2143 is in direct contact with the first electron control layer 2150 and forms an interface. Thus, since the first electron transfer layer 2160 is included in the blue sub-organic light emitting device 2000_B, even if a recombination zone of the blue sub-organic light emitting device 2000_B is optimized, the red sub-organic light emitting device 2000_R or the green sub-organic light emitting device 2000_G is not affected at all. That is, among the first red organic emission layer 2141, the first green organic emission layer 2142, the first blue organic emission layer 2143, only the first blue organic emission layer 2143 forms an interface with the first electron control layer 2150. Thus, it is possible to configure the first electron control layer 2150 only considering formation of a recombination zone of the blue sub-organic light emitting device 2000_B without a need to consider formation of recombination zones of the red sub-organic light emitting device 2000_R and the green sub-organic light emitting device 2000_G.

The first electron control layer 2150 may be disposed considering optimization of a recombination zone in the blue sub-organic light emitting device 2000_B. In this case, the first electron control layer 2150 may be configured to have a thickness of more than 3% to less than 5% of a thickness of the blue sub-organic light emitting device 2000_B. If a thickness of the first electron control layer 2150 is equal to or less than 3% of a thickness of the blue sub-organic light emitting device 2000_B, the above-described effect may not be shown in the blue sub-organic light emitting device 2000_B. Therefore, the first electron control layer 2150 may have a thickness of more than 3% of a thickness of at least the blue sub-organic light emitting device 2000_B. Further, if a thickness of the first electron control layer 2150 is equal to or more than 5% of a thickness of the blue sub-organic light emitting device 2000_B, a recombination zone may be formed inclining to the cathode within the first blue organic emission layer 2143 or may be formed over an interface on the cathode side of the first blue organic emission layer 2143. Thus, luminous efficiency of the organic light emitting device 2000 may be decreased. Further, the amount of excitons converted into heat energy is increased, which may accelerate interface degradation and increase a driving voltage. Therefore, the first electron control layer 2150 may have a thickness of less than 5% of a thickness of at least the blue sub-organic light emitting device 2000_B.

Hereinafter, a relationship among the first blue organic emission layer 2143, the first electron control layer 2150, and the first electron transfer layer 2160 will be described with reference to FIG. 2B.

FIG. 2B is an LUMO energy diagram illustrating LUMO energy levels of layers respectively corresponding to electron transfer routes in the first emission unit 2100 according to the second exemplary embodiment of the present disclosure. The organic light emitting device 2000 according to the second exemplary embodiment of the present disclosure is designed such that an energy barrier is minimized when an electron moves from the first electron transfer layer 2160 to the first blue organic emission layer 2143. Specifically, if the first blue organic emission layer 2143 and the first electron control layer 2150 are in contact with each other and form an interface, an absolute value of an LUMO energy level of the first electron control layer 2150 is lower than an absolute value of an LUMO energy level of the first blue organic emission layer 2143. Further, if the first electron control layer 2150 and the first electron transfer layer 2160 are in contact with each other and form an interface, an absolute value of an LUMO energy level of the first electron transfer layer 2160 is equal to or lower than the absolute value of the LUMO energy level of the first electron control layer 2150. That is, the absolute value of the LUMO energy level of the first electron transfer layer 2160 is equal to or lower than the absolute value of the LUMO energy level of the first electron control layer 2150, and the absolute value of the LUMO energy level of the first electron control layer 2150 is lower than the absolute value of the LUMO energy level of the first blue organic emission layer 2143. Herein, the absolute value of an LUMO energy level of the first blue organic emission layer 2143 may be an absolute value of an LUMO energy level of a host material included in the first blue organic emission layer 2143.

The absolute value of the LUMO energy level of the blue host material included in the first blue organic emission layer 2143 is higher than the absolute value of the LUMO energy level of the first electron control layer 2150. Thus, an electron can easily move from the first electron control layer 2150 to the first blue organic emission layer 2143. Further, the absolute value of the LUMO energy level of the first electron control layer 2150 is equal to or higher than the absolute value of the LUMO energy level of the first electron transfer layer 2160. Thus, an electron can easily move from the first electron transfer layer 2160 to the first electron control layer 2150.

In other words, among the first blue organic emission layer 2143, the first electron control layer 2150, and the first electron transfer layer 2160, the first blue organic emission layer 2143 may have the lowest LUMO energy level and the first electron transfer layer 2160 may have the highest LUMO energy level. This is not necessarily limited to a case where the first blue organic emission layer 2143, the first electron control layer 2150, and the first electron transfer layer 2160 are in direct contact with each other and form interfaces. Thus, in the organic light emitting device 2000 according to the second exemplary embodiment, an energy barrier to be overcome by an electron moving from the first electron transfer layer 2160 to the first blue organic emission layer 2143 is minimized. Since the electron can move to the first blue organic emission layer 2143 without difficulty in overcoming the energy barrier, a driving voltage of the organic light emitting device 2000 can be reduced.

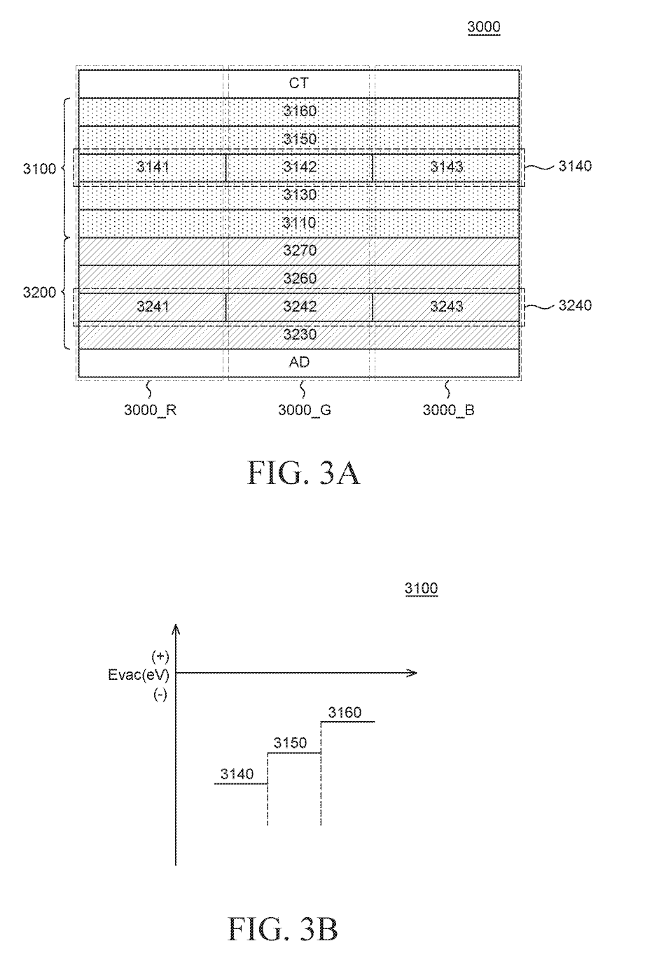

FIG. 3A is a cross-sectional view illustrating an organic light emitting device 3000 according to a third exemplary embodiment of the present disclosure. Referring to FIG. 3A, the organic light emitting device 3000 according to the third exemplary embodiment of the present disclosure includes a first emission unit 3100 and a second emission unit 3200 between an anode AD and a cathode CT facing and spaced apart from each other. The first emission unit 3100 may include a first hole injection layer, a first hole transfer layer 3130, a first organic emission layer 3140, a first electron control layer 3150, and a first electron transfer layer 3160. Herein, the first organic emission layer 3140 includes a first red organic emission layer 3141, a first green organic emission layer 3142, and a first blue organic emission layer 3143. Further, the second emission unit 3200 may include a second hole injection layer, a second hole transfer layer 3230, a second organic emission layer 3240, and a second electron transfer layer 3260. Herein, the second organic emission layer 3240 includes a second red organic emission layer 3241, a second green organic emission layer 3242, and a second blue organic emission layer 3243. That is, the organic light emitting device 3000 according to the third exemplary embodiment of the present disclosure has a structure in which the two or more organic emission layers 3140 and 3240 are laminated.

The organic light emitting device 3000 according to the third exemplary embodiment of the present disclosure illustrated in FIG. 3A is an modification example of the organic light emitting device 1000 according to the first exemplary embodiment of the present disclosure illustrated in FIG. 1A. That is, the organic light emitting device 3000 according to the third exemplary embodiment illustrated in FIG. 3A is an example in which the second emission unit 3200 is additionally laminated in the organic light emitting device 1000 according to the first exemplary embodiment illustrated in FIG. 1A.

The organic light emitting device 3000 of the third exemplary embodiment is illustrated as including two emission units, i.e., the first emission unit 3100 and the second emission unit 3200 for convenience, but is not limited thereto. The organic light emitting device 3000 of the third exemplary embodiment may include three or more emission units. Herein, the first emission unit 3100 is an emission unit in which a P-type charge generation layer 3110 is added to the first emission unit 1100 of the first exemplary embodiment. In this case, the P-type charge generation layer 4110 may be replaced to the first hole injection layer. Further, the second emission unit 3200 is an emission unit in which an N-type charge generation layer 3270 is added and the first electron control layer 1150 is omitted from the first emission unit 1100 of the first exemplary embodiment. Therefore, the same descriptions of the components of the first emission unit 1100 according to the first exemplary embodiment of the present disclosure illustrated in FIG. 1A may also be applied to the components of the first emission unit 3100 according to the third exemplary embodiment of the present disclosure illustrated in FIG. 3A. That is, the above descriptions of the anode AD, the cathode CT, the first hole injection layer 1120, the first hole transfer layer 1130, the first organic emission layer 1140, the first red organic emission layer 1141, the first green organic emission layer 1142, the first blue organic emission layer 1143, the first electron control layer 1150, and the first electron transfer layer 1160 of the organic light emitting device 1000 according to the first exemplary embodiment of the present disclosure may also be respectively applied to the anode AD, the cathode CT, the first hole injection layer, the first hole transfer layer 3130, the first organic emission layer 3140, a first red organic emission layer 3141, a first green organic emission layer 3142, a first blue organic emission layer 3143, the first electron control layer 3150, and the first electron transfer layer 3160 of the organic light emitting device 3000 according to the third exemplary embodiment of the present disclosure. Furthermore, the same descriptions of the components of the first emission unit 1100 according to the first exemplary embodiment of the present disclosure illustrated in FIG. 1A may also be applied to the components of the second emission unit 3200 according to the third exemplary embodiment of the present disclosure illustrated in FIG. 3A. That is, the above descriptions of the first hole injection layer 1120, the first hole transfer layer 1130, the first organic emission layer 1140, the first red organic emission layer 1141, the first green organic emission layer 1142, the first blue organic emission layer 1143, and the first electron transfer layer 1160 of the organic light emitting device 1000 according to the first exemplary embodiment of the present disclosure may also be respectively applied to the second hole injection layer, the second hole transfer layer 3230, the second organic emission layer 3240, a second red organic emission layer 3241, a second green organic emission layer 3242, a second blue organic emission layer 3243, and the second electron transfer layer 3260 of the organic light emitting device 3000 according to the third exemplary embodiment of the present disclosure. Therefore, in describing the organic light emitting device 3000 according to the third exemplary embodiment of the present disclosure, redundant descriptions will be omitted and modified or added parts such as the P-type charge generation layer 3110 and the N-type charge generation layer 3270 will be described.

The N-type charge generation layer 3270 injects an electron into the second organic emission layer 3240 of the second emission unit 3200. The N-type charge generation layer 3270 may include an N-type dopant material and an N-type host material. The N-type dopant material may include metals from Group 1 and Group 2 on the periodic table, electron-injectable organic materials, or mixtures thereof. For example, the N-type dopant material may be any one of alkali metals and alkali earth metals. That is, the N-type charge generation layer may be formed as an organic layer doped with an alkali metal such as lithium (Li), sodium (Na), potassium (K), or cesium (Cs), or an alkali earth metal such as magnesium (Mg), strontium (Sr), barium (Ba), or radium (Ra), but is not limited thereto. The N-type host material may include any one or more of materials capable of transferring electrons, e.g., Alq3(Tris(8-hydroxyquinolino)aluminum), Liq(8-hydroxyquinolinolato-lithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, and BAlq(bis(2-methyl-8-quinolinolate)-4-(phenylphenolato)aluminium), SAlq, TPBi(2,2′,2″-(1,3,5-benzinetriyl)-tris(1-phenyl-1-H-benzimidazole), oxadiazole, triazole, phenanthroline, benzoxazole, or benzthiazole, but is not limited thereto.

The P-type charge generation layer 3110 injects a hole into the first organic emission layer 3140 of the first emission unit 3100. The P-type charge generation layer 3110 may include a P-type dopant material and a P-type host material. The P-type charge generation layer 3110 forms an interface with the N-type charge generation layer 3270. That is, the P-type charge generation layer 3110 has a structure bonded to the N-type charge generation layer 3270. The P-type dopant material may include metal oxides, organic materials such as tetrafluoro tetracyanoquinodimethane (F4-TCNQ), HAT-CN (hexaazatriphenylene-hexacarbonitrile), and hexaazatriphenylene, or metallic oxide materials such as V₂O₅, MoOx, WO₃, etc., but is not limited thereto. The P-type host material may include any one or more of materials capable of transferring holes, e.g., NPD (N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), and MTDATA (4,4′,4″-Tris(N-3-methylphenyl-N-phenyl-amino)-triphenylamine), but is not limited thereto.

The first electron control layer 3150 of the organic light emitting device 3000 of the third exemplary embodiment of the present disclosure also functions as a kind of booster in the same manner as the first electron control layer 1150 of the organic light emitting device 1000 of the first exemplary embodiment. Thus, an electron more rapidly reaches the first organic emission layer 3140. Therefore, a recombination zone formed by combination of electrons and holes can be located entirely within the first organic emission layer 3140 and light energy can be generated by excitons more effectively.

The above-described effect can be maximized particularly in a blue sub-organic light emitting device 3000_B. A red sub-organic light emitting device 3000_R and a green sub-organic light emitting device 3000_G are thicker than the blue sub-organic light emitting device 3000_B. Thus, if the first electron control layer 3150 is thin enough, a recombination zone of the blue sub-organic light emitting device 3000_B may be optimized with the first electron control layer 3150. Even in this case, the red sub-organic light emitting device 3000_R and the green sub-organic light emitting device 3000_G are not greatly affected. Therefore, in the organic light emitting device 3000 of the third exemplary embodiment, one entire surface of the first organic emission layer 3140 and the first electron control layer 3150 are in direct contact with each other and forms an interface. In other words, all of the first red organic emission layer 3141, the first green organic emission layer 3142, and the first blue organic emission layer 3143 respectively form interfaces with the first electron control layer 3150. Thus, it is not necessary to allow an interface with the first electron control layer 3150 to be present in only some of the red sub-organic light emitting device 3000_R, the green sub-organic light emitting device 3000_G, and the blue sub-organic light emitting device 3000_B. Therefore, it is not necessary to use a fine metal mask in order to form the first electron control layer 3150. As a result, there is no difficulty of aligning sub-organic light emitting devices, and, thus, the organic light emitting device 3000 of the third exemplary embodiment of the present disclosure can be manufactured by a relatively easy process.

In the organic light emitting device 3000 of the third exemplary embodiment of the present disclosure, positions of the first organic emission layer 3140 and the second organic emission layer 3240 may be determined considering the optical conditions for constructive interference. Therefore, the first emission unit 3100 may be configured to have a smaller thickness than the second emission unit 3200. In the first emission unit 3100 having a smaller thickness than the second emission unit 3200, a distance from the P-type charge generation layer 3110 to the first organic emission layer 3140 is not long enough, and, thus, a hole may rather rapidly reach the first organic emission layer 3140. In order to compensate this phenomenon, the first electron control layer 3150 functioning as a booster is disposed in the first emission unit 3110. In this case, the first emission unit 3110 having a smaller thickness than the second emission unit 3200 may be closer to the cathode CT than the second emission unit 3200. In other words, among a plurality of organic emission layers 3140 and 3240, an organic emission layer closest to the cathode may form an interface with the first electron control layer 3150. That is, the first organic emission layer 3140 may be an organic emission layer which is closest to the cathode and also forms an interface with the first electron control layer 3150.

Thus, it is possible to minimize slight inclination of a recombination zone of the first emission unit 3100 with respect to the first organic emission layer 3140. That is, since the first emission unit 3100 having a relatively small thickness includes the first electron control layer 3150, the probability of forming excitons by electrons and holes within the first organic emission layer 3140 can be increased. A formation position of excitons is optimized, and, thus, useless dissipation of excitons in the form of heat energy can be minimized and conversion of excitons into light energy can be maximized. Thus, luminous efficiency of the organic light emitting device 3000 can be improved.

Hereinafter, a relationship among the first organic emission layer 3140, the first electron control layer 3150, and the first electron transfer layer 3160 will be described with reference to FIG. 3B.

FIG. 3B is an LUMO energy diagram illustrating LUMO energy levels of layers respectively corresponding to electron transfer routes in the first emission unit 3100 according to the third exemplary embodiment of the present disclosure. The organic light emitting device 3000 according to the third exemplary embodiment of the present disclosure is designed such that an energy barrier is minimized when an electron moves from the first electron transfer layer 3160 to the first organic emission layer 3140. Specifically, if the first organic emission layer 3140 and the first electron control layer 3150 are in contact with each other and form an interface, an absolute value of an LUMO energy level of the first electron control layer 3150 is lower than an absolute value of an LUMO energy level of the first organic emission layer 3140. Further, if the first electron control layer 3150 and the first electron transfer layer 3160 are in contact with each other and form an interface, an absolute value of an LUMO energy level of the first electron transfer layer 3160 is equal to or lower than the absolute value of the LUMO energy level of the first electron control layer 3150. That is, the absolute value of the LUMO energy level of the first electron transfer layer 3160 is equal to or lower than the absolute value of the LUMO energy level of the first electron control layer 3150, and the absolute value of the LUMO energy level of the first electron control layer 3150 is lower than the absolute value of the LUMO energy level of the first organic emission layer 3140. Herein, the absolute value of an LUMO energy level of the first organic emission layer 3140 may be an absolute value of an LUMO energy level of a host material included in the first organic emission layer 3140.

If an electric field is applied to an organic light emitting device, an electron moves along an LUMO energy level of the organic light emitting device. Herein, the electron can easily move from a place having a higher LUMO energy level to a place having a lower LUMO energy level as compared with a case where the electron moves in reverse. That is, the electron can easily move from a place having a lower absolute value of an LUMO energy level to a place having a higher absolute value of an LUMO energy level as compared with a case where the electron moves in reverse. For example, if an electron moves from a place having a higher LUMO energy level to a place having a lower LUMO energy level, it may mean that an energy barrier is not present. It is advantageous to reduce an energy barrier as much as possible in terms of (1) an easiness in movement of an electron and (2) a decrease in interface heating which is a cause of interface degradation.

An absolute value of an LUMO energy level of each of a plurality of host materials (i.e., a red host material, a green host material, and a blue host material) in the first organic emission layer 3140 is higher than the absolute value of the LUMO energy level of the first electron control layer 3150. Thus, an electron can easily move from first electron control layer 3150 to the first organic emission layer 3140. Further, the absolute value of the LUMO energy level of the first electron control layer 3150 is equal to or higher than the absolute value of the LUMO energy level of the first electron transfer layer 3160. Thus, an electron can easily move from the first electron transfer layer 3160 to the first electron control layer 3150.

In other words, among the first organic emission layer 3140, the first electron control layer 3150, and the first electron transfer layer 3160, the first organic emission layer 3140 may have the lowest LUMO energy level and the first electron transfer layer 3160 may have the highest LUMO energy level. This is not necessarily limited to a case where the first organic emission layer 3140, the first electron control layer 3150, and the first electron transfer layer 3160 are in direct contact with each other and form interfaces. Thus, in the organic light emitting device 3000 according to the third exemplary embodiment, an energy barrier to be overcome by an electron moving from the first electron transfer layer 3160 to the first organic emission layer 3140 is minimized. Since the electron can move to the first organic emission layer 3140 without difficulty in overcoming the energy barrier, a driving voltage of the organic light emitting device 3000 can be reduced.

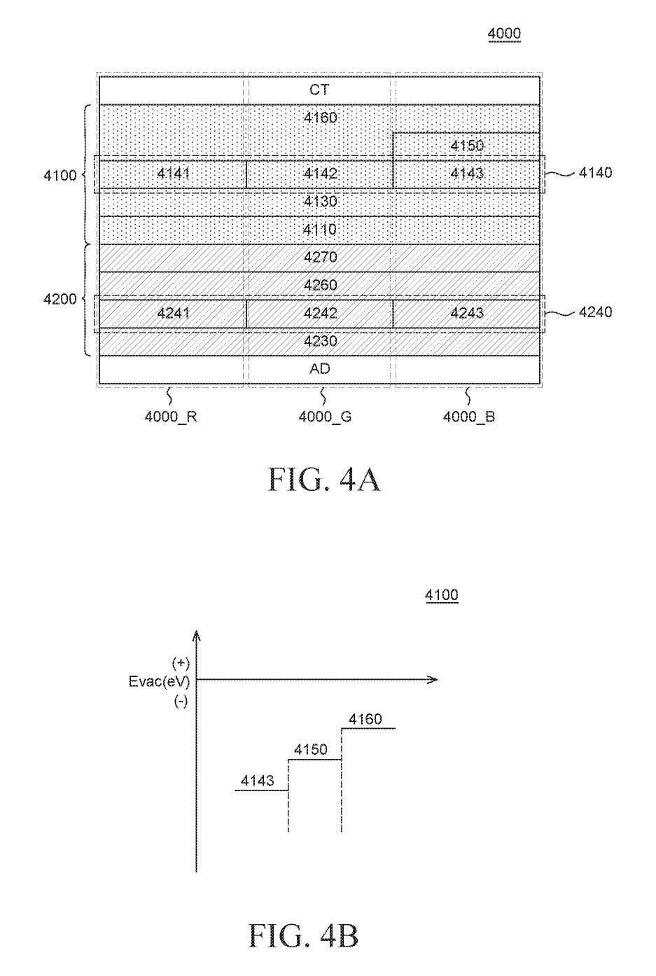

FIG. 4A is a cross-sectional view illustrating an organic light emitting device 4000 according to a fourth exemplary embodiment of the present disclosure. Referring to FIG. 4A, the organic light emitting device 4000 according to the fourth exemplary embodiment of the present disclosure includes a first emission unit 4100 and a second emission unit 4200 between an anode AD and a cathode CT facing and spaced apart from each other. The first emission unit 4100 includes a first hole injection layer, a first hole transfer layer 4130, a first organic emission layer 4140, a first electron control layer 4150, and a first electron transfer layer 4160. Herein, the first organic emission layer 4140 includes a first red organic emission layer 4141, a first green organic emission layer 4142, and a first blue organic emission layer 4143. Further, the second emission unit 4200 includes a second hole injection layer, a second hole transfer layer 4230, a second organic emission layer 4240, and a second electron transfer layer 4260. Herein, the second organic emission layer 4240 includes a second red organic emission layer 4241, a second green organic emission layer 4242, and a second blue organic emission layer 4243.

The organic light emitting device 4000 according to the fourth exemplary embodiment of the present disclosure illustrated in FIG. 4A is an modification example of the organic light emitting device 2000 according to the second exemplary embodiment of the present disclosure illustrated in FIG. 2A and also an modification example of the organic light emitting device 3000 according to the third exemplary embodiment of the present disclosure illustrated in FIG. 3A. That is, the organic light emitting device 4000 according to the fourth exemplary embodiment illustrated in FIG. 4A is an example in which the second emission unit 4200 is additionally laminated in the organic light emitting device 2000 according to the second exemplary embodiment illustrated in FIG. 2A. That is, similar to the organic light emitting device 3000 according to the third exemplary embodiment illustrated in FIG. 3A, the organic light emitting device 4000 according to the fourth exemplary embodiment illustrated in FIG. 4A is an organic light emitting device in which a plurality of emission units is laminated. Therefore, similar to the organic light emitting device 3000 according to the third exemplary embodiment, the organic light emitting device 4000 according to the fourth exemplary embodiment of the present disclosure illustrated in FIG. 4A also includes charge generation layers 4110 and 4270.

The organic light emitting device 4000 of the fourth exemplary embodiment is illustrated as including two emission units, i.e., the first emission unit 4100 and the second emission unit 4200 for convenience, but is not limited thereto. The organic light emitting device 4000 of the fourth exemplary embodiment may include three or more emission units. Herein, the first emission unit 4100 is an emission unit in which a P-type charge generation layer 4110 is added to the first emission unit 2100 of the second exemplary embodiment. In this case, the P-type charge generation layer 4110 may be replaced to the first hole injection layer. Further, the second emission unit 4200 is an emission unit in which an N-type charge generation layer 4270 is added and the first electron control layer 2150 is omitted from the first emission unit 2100 of the second exemplary embodiment. Therefore, the same descriptions of the components of the first emission unit 2100 according to the second exemplary embodiment of the present disclosure illustrated in FIG. 2A may also be applied to the components of the first emission unit 4100 according to the fourth exemplary embodiment of the present disclosure illustrated in FIG. 4A. That is, the above descriptions of the anode AD, the cathode CT, the first hole injection layer 2120, the first hole transfer layer 2130, the first organic emission layer 2140, the first red organic emission layer 2141, the first green organic emission layer 2142, the first blue organic emission layer 2143, the first electron control layer 2150, and the first electron transfer layer 2160 of the organic light emitting device 2000 according to the second exemplary embodiment of the present disclosure may also be respectively applied to the anode AD, the cathode CT, the first hole injection layer, the first hole transfer layer 4130, the first organic emission layer 4140, a first red organic emission layer 4141, a first green organic emission layer 4142, a first blue organic emission layer 4143, the first electron control layer 4150, and the first electron transfer layer 4160 of the organic light emitting device 4000 according to the fourth exemplary embodiment of the present disclosure. Furthermore, the same descriptions of the components of the first emission unit 2100 according to the second exemplary embodiment of the present disclosure illustrated in FIG. 2A may also be applied to the components of the second emission unit 4200 according to the fourth exemplary embodiment of the present disclosure illustrated in FIG. 4A. That is, the above descriptions of the first hole injection layer 2120, the first hole transfer layer 2130, the first organic emission layer 2140, the first red organic emission layer 2141, the first green organic emission layer 2142, the first blue organic emission layer 2143, and the first electron transfer layer 2160 of the organic light emitting device 2000 according to the second exemplary embodiment of the present disclosure may also be respectively applied to the second hole injection layer, the second hole transfer layer 4230, the second organic emission layer 4240, a second red organic emission layer 4241, a second green organic emission layer 4242, a second blue organic emission layer 4243, and the second electron transfer layer 4260 of the organic light emitting device 4000 according to the fourth exemplary embodiment of the present disclosure. Furthermore, the same descriptions of the P-type charge generation layer 3110 and the N-type charge generation layer 3270 according to the third exemplary embodiment of the present disclosure illustrated in FIG. 3A are also respectively applied to the P-type charge generation layer 4110 and the N-type charge generation layer 4270 according to the fourth exemplary embodiment of the present disclosure illustrated in FIG. 4A. Therefore, in describing the organic light emitting device 4000 according to the fourth exemplary embodiment of the present disclosure, redundant descriptions will be omitted and modified or added parts will be described.

The first electron control layer 4150 of the organic light emitting device 4000 of the fourth exemplary embodiment of the present disclosure also functions as a kind of booster in the same manner as the first electron control layer 2150 of the organic light emitting device 2000 of the second exemplary embodiment. Thus, an electron more rapidly reaches the first blue organic emission layer 4143. Therefore, a recombination zone formed by combination of electrons and holes can be located entirely within the first blue organic emission layer 4143 and light energy can be generated by excitons more effectively.

The above-described effect can be maximized particularly in a blue sub-organic light emitting device 4000_B having a small thickness. Therefore, the first electron transfer layer 4160 may be disposed only in the blue sub-organic light emitting device 4000_B in order not to affect a red sub-organic light emitting device 4000_R or a green sub-organic light emitting device 4000_G. In other words, in the organic light emitting device 4000 of the fourth exemplary embodiment, among surfaces of the first organic emission layer 4140, only one surface corresponding to the first blue organic emission layer 4143 is in direct contact with the first electron control layer 4150 and forms an interface. Thus, since the first electron transfer layer 4160 is included in the blue sub-organic light emitting device 4000_B, even if a recombination zone of the blue sub-organic light emitting device 4000_B is optimized, the red sub-organic light emitting device 4000_R or the green sub-organic light emitting device 4000_G is not affected at all. That is, among the first red organic emission layer 4141, the first green organic emission layer 4142, the first blue organic emission layer 4143, only the first blue organic emission layer 4143 forms an interface with the first electron control layer 4150. Thus, it is possible to configure the first electron control layer 4150 only considering formation of a recombination zone of the blue sub-organic light emitting device 4000_B without a need to consider formation of recombination zones of the red sub-organic light emitting device 4000_R and the green sub-organic light emitting device 4000_G.

In the organic light emitting device 4000 according to the fourth exemplary embodiment similar to the organic light emitting device 3000 according to the third exemplary embodiment, positions of the first organic emission layer 4140 and the second organic emission layer 4240 may also be determined considering the optical conditions for constructive interference. Therefore, the first emission unit 4100 may be configured to have a smaller thickness than the second emission unit 4200. In the first emission unit 4100 having a smaller thickness than the second emission unit 4200, a distance from the P-type charge generation layer 4110 to the first organic emission layer 4140 is not long enough, and, thus, a hole may rather rapidly reach the first organic emission layer 4140. In order to compensate this phenomenon, the first electron control layer 4150 functioning as a booster is disposed in the first emission unit 4110. In this case, the first emission unit 4110 having a smaller thickness than the second emission unit 4200 may be closer to the cathode CT than the second emission unit 4200. In other words, among a plurality of organic emission layers 4140 and 4240, an organic emission layer closest to the cathode may form an interface with the first electron control layer 4150. That is, the first organic emission layer 4140 may be an organic emission layer which is closest to the cathode and also forms an interface with the first electron control layer 4150.

Thus, it is possible to minimize slight inclination of a recombination zone of the first emission unit 4100 with respect to the first organic emission layer 4140. That is, since the first emission unit 4100 having a relatively small thickness includes the first electron control layer 4150, the probability of forming excitons by electrons and holes within the first organic emission layer 4140 can be increased. A formation position of excitons is optimized, and, thus, useless dissipation of excitons in the form of heat energy can be minimized and conversion of excitons into light energy can be maximized. Thus, luminous efficiency of the organic light emitting device 4000 can be improved.

The exemplary embodiments of the present disclosure can also be described as follows.

According to an aspect of the present disclosure, there is provided an organic light emitting device. The organic light emitting device includes an anode and a cathode facing and spaced apart from each other, an organic emission layer including a host material doped with a dopant material, an electron control layer between the organic emission layer and the cathode and configured to provide an interface with the organic emission layer, and an electron transfer layer between the electron control layer and the cathode, configured to provide an interface with the electron control layer, having a lower electron mobility than electron mobility of the electron control layer, and having an absolute value of a lowest unoccupied molecular orbital (LUMO) energy level equal to or lower than an absolute value of a LUMO energy level of the electron control layer.

The organic light emitting device may be configured to emit a blue light from the organic emission layer.

The organic emission layer may include a blue dopant material, and the absolute value of the LUMO energy level of the electron control layer may be lower than an absolute value of a LUMO energy level of the host material.

The blue dopant material may be a fluorescent dopant material.

The thickness of the electron control layer may be more than 3% to less than 5% of a total thickness of the organic light emitting device.

The organic emission layer includes a red organic emission layer, a green organic emission layer, and a blue organic emission layer. When a portion where the red organic emission layer is located between the anode and the cathode acts as a red sub-organic light emitting device, a portion where the green organic emission layer is located between the anode and the cathode acts as a green sub-organic light emitting device and a portion where the blue organic emission layer is located between the anode and the cathode acts as a blue sub-organic light emitting device, the blue sub-organic light emitting device may have the smallest thickness among the thickness of the red sub-organic light emitting device, the thickness of the green sub-organic light emitting device, and the thickness of the blue sub-organic light emitting device.

Among the red organic emission layer, the green organic emission layer, and the blue organic emission layer, only the blue organic emission layer may form an interface with the electron control layer.

A host material included in the blue organic emission layer may be a blue host material, and an absolute value of a LUMO energy level of the blue host material may be higher than the absolute value of the LUMO energy level of the electron control layer.

All of the red organic emission layer, the green organic emission layer, and the blue organic emission layer may form interfaces with the electron control layer.

A host material included in the red organic emission layer may be a red host material, a host material included in the green organic emission layer may be a green host material, and a host material included in the blue organic emission layer may be a blue host material. an absolute value of a LUMO energy level of the red host material, an absolute value of a LUMO energy level of the green host material, and an absolute value of a LUMO energy level of the blue host material may be all higher than the absolute value of the LUMO energy level of the electron control layer.

The organic light emitting device has a structure in which the two or more organic emission layers are laminated, and among the two or more organic emission layers, an organic emission layer closest to the cathode may form an interface with the electron control layer.

The thickness of the electron transfer layer may be greater than a thickness of the electron control layer.

The organic light emitting device may have a top-emission structure in which a light is emitted toward the cathode.

Although the exemplary embodiments of the present disclosure have been described in detail with reference to the accompanying drawings, the present disclosure is not limited thereto and may be embodied in many different forms without departing from the technical concept of the present disclosure. Therefore, the various exemplary embodiments of the present disclosure are provided for illustrative purposes only but not intended to limit the technical concept of the present disclosure. The scope of the technical concept of the present disclosure is not limited thereto. Therefore, it should be understood that the above-described various exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An organic light emitting device comprising:
an anode and a cathode facing each other and spaced apart from each other;
an organic emission layer including a host material doped with a dopant material;
an electron control layer between the organic emission layer and the cathode, and configured to provide an interface with the organic emission layer; and
an electron transfer layer between the electron control layer and the cathode, and configured to provide an interface with the electron control layer,
the electron transfer layer having a lower electron mobility than an electron mobility of the electron control layer, and having an absolute value of a lowest unoccupied molecular orbital (LUMO) energy level equal to or lower than an absolute value of a LUMO energy level of the electron control layer.

2. The organic light emitting device according to claim 1, wherein the organic light emitting device is configured to emit a blue light.

3. The organic light emitting device according to claim 2, wherein the organic emission layer includes a blue dopant material, and
the absolute value of the LUMO energy level of the electron control layer is lower than an absolute value of a LUMO energy level of the host material.

4. The organic light emitting device according to claim 3, wherein the blue dopant material is a fluorescent dopant material.

5. The organic light emitting device according to claim 2, wherein a thickness of the electron control layer is more than 3% to less than 5% of a total thickness of the organic light emitting device.

6. The organic light emitting device according to claim 1, wherein the organic emission layer includes a red organic emission layer, a green organic emission layer, and a blue organic emission layer, and
when a portion where the red organic emission layer is located between the anode and the cathode acts as a red sub-organic light emitting device, a portion where the green organic emission layer is located between the anode and the cathode acts as a green sub-organic light emitting device and a portion where the blue organic emission layer is located between the anode and the cathode acts as a blue sub-organic light emitting device,
the blue sub-organic light emitting device has the smallest thickness among the thickness of the red sub-organic light emitting device, the thickness of the green sub-organic light emitting device, and the thickness of the blue sub-organic light emitting device.

7. The organic light emitting device according to claim 6, wherein among the red organic emission layer, the green organic emission layer, and the blue organic emission layer, only the blue organic emission layer forms an interface with the electron control layer.

8. The organic light emitting device according to claim 7, wherein a host material included in the blue organic emission layer is a blue host material, and
an absolute value of a LUMO energy level of the blue host material is higher than the absolute value of the LUMO energy level of the electron control layer.

9. The organic light emitting device according to claim 6, wherein all of the red organic emission layer, the green organic emission layer, and the blue organic emission layer form interfaces with the electron control layer.

10. The organic light emitting device according to claim 9, wherein a host material included in the red organic emission layer is a red host material, a host material included in the green organic emission layer is a green host material, and a host material included in the blue organic emission layer is a blue host material, and
an absolute value of a LUMO energy level of the red host material, an absolute value of a LUMO energy level of the green host material, and an absolute value of a LUMO energy level of the blue host material are all higher than the absolute value of the LUMO energy level of the electron control layer.

11. The organic light emitting device according to claim 6, wherein the organic light emitting device has a structure in which the two or more organic emission layers are laminated, and
among the two or more organic emission layers, an organic emission layer closest to the cathode forms an interface with the electron control layer.

12. The organic light emitting device according to claim 1, wherein a thickness of the electron transfer layer is greater than a thickness of the electron control layer.

13. The organic light emitting device according to claim 1, wherein the organic light emitting device has a top-emission structure in which a light is emitted toward the cathode.
